(19) United States
(12) Patent Application Publication
(10) Pub. No.: US 2008/0081453 A1
(43) Pub. Date: Apr. 3, 2008

(54) Method of forming metal wire of semiconductor device

(75) Inventors: Jung Geun Kim, Seoul (KR); Cheol Mo Jeong, Icheon-si (KR); Eun Soo Kim, Incheon-Si (KR); Seung Hee Hong, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/603,752

(22) Filed: Nov. 22, 2006

(30) Foreign Application Priority Data
Sep. 29, 2006 (KR) 2006-96177

(51) Int. Cl. H01L 21/44

(52) U.S. Cl. 438/597

(57) ABSTRACT

A method of forming a metal line of a semiconductor device includes the steps of forming an insulating layer and a glue layer on a semiconductor substrate, removing a portion of the glue layer and the insulating layer to form trenches, forming a metal layer over the semiconductor substrate including the trenches and the glue layer, and performing a polishing process until the insulating layer is exposed, thus forming a metal line.

### BACKGROUND OF THE INVENTION

1. Field of the Invention

The invention relates, in general, to semiconductor devices and, more particularly to a method of forming a metal line of a semiconductor device, which is capable of reducing line resistance by omitting a barrier metal layer formation process

2. Related Technology

In devices of 70 nm and 60 nm in size, if a metal line is formed by a general damascene structure, the following problems occur.

First, as the pitch of the metal line decreases, the resistance value of the metal line abruptly rises. This is illustrated in the graph of FIG. 1.

From FIG. 1, it can be seen that as the design rules of a device decrease, resistance values and capacitance values abruptly rise.

Second, if the metal line is formed by a single damascene structure, a problem arises because the resistance of the metal line increases due to the area occupied by a barrier metal layer within a trench. For this reason, attempts have been made to secure the resistance of the metal line by reducing the thickness of the barrier metal layer. However, a reduction in the thickness of the barrier metal layer has reached a limit in 60 nm or less, as illustrated in FIG. 2.

Third, attempts have been made to improve a resistance characteristic of the metal line by minimizing a tungsten nucleus creation target with a high resistivity. However, a reduction in tungsten nucleus creation has reached a limit in 60 nm or less, as illustrated in FIG. 2.

Fourth, the larger the grain size, the lower the resistivity of tungsten. However, the grain size of tungsten is dependent on the Critical Dimension (CD) of the trench. Thus, the grain size inevitably reduces since the CD of the trench decreases.

Fifth, if tungsten is deposited on an insulating layer, a lifting phenomenon occurs between the insulating layer and tungsten due to an adhesion problem. Thus, titanium (Ti) and a titanium nitride (TiN) layer between the insulating layer and tungsten have been used as glue layers. However, tungsten nuclei are not sufficiently generated on the TiN layer. Accordingly, the grain growth is fast, but the grain size is decreased, leading to decreased resistivity.

### SUMMARY OF THE INVENTION

Embodiments of the invention are directed to a method of forming a metal line of a semiconductor device, which is capable of reducing line resistance by omitting a barrier metal layer formation process.

In one embodiment, a method of forming a metal line of a semiconductor device includes the steps of forming an insulating layer and a glue layer on a semiconductor substrate, removing a portion of the glue layer and the insulating layer to form trenches, forming a metal layer over the semiconductor substrate including the trenches and the glue layer, and performing a polishing process until the insulating layer is exposed, thus forming a metal line.

### BRIEF DESCRIPTION OF THE DRAWINGS

FIG. 1 is a graph showing resistance values and capacitance values, which are increased as the design rule of a device is decreased.

FIG. 2 is a graph showing resistance values and capacitance values, which are decreased as a thickness of each of a barrier metal layer and a tungsten nucleus target is decreased.

FIGS. 3A to 3E are cross-sectional views illustrating a method of forming a metal line of a semiconductor device according to an embodiment of the invention.

FIG. 4 is a view illustrating a Low Rs W (LRW) method according to the invention.

FIG. 5 is a graph showing resistance values and capacitance values when the invention is applied.

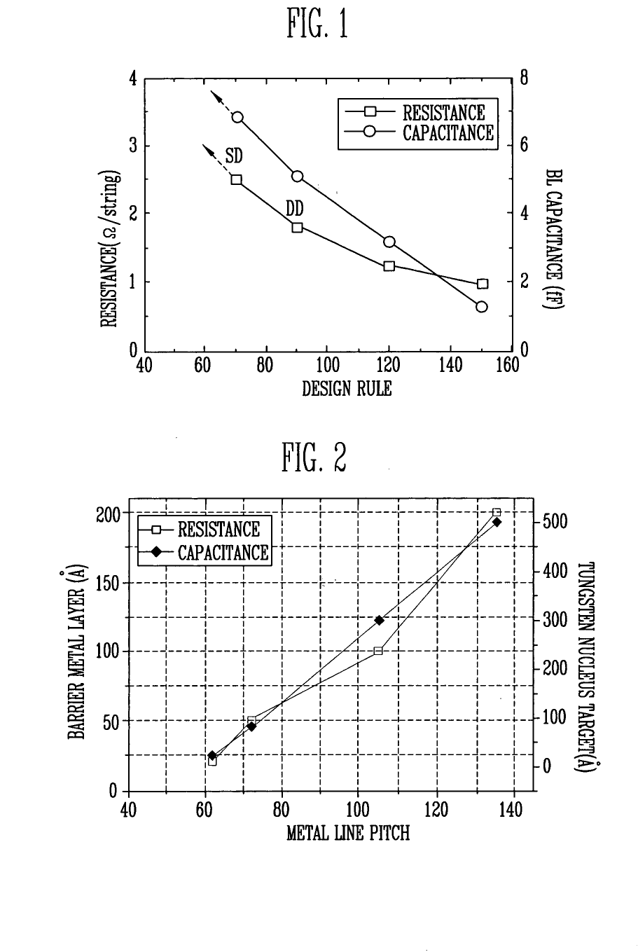

### DESCRIPTION OF SPECIFIC EMBODIMENTS

Specific embodiments according to the invention are described below with reference to the accompanying drawings.

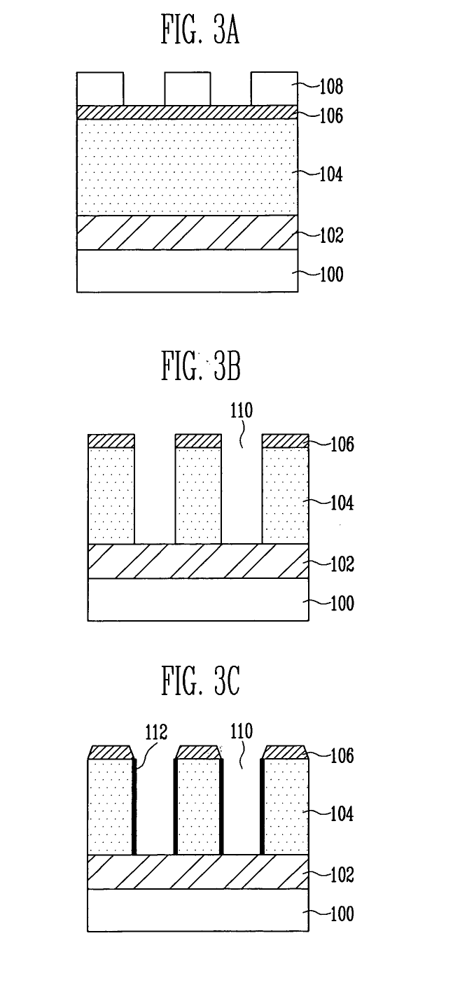

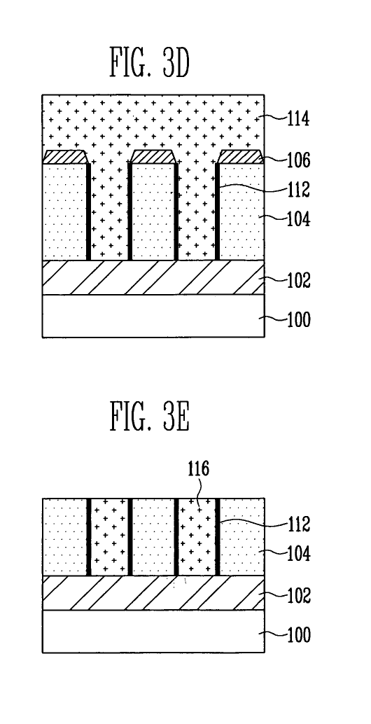

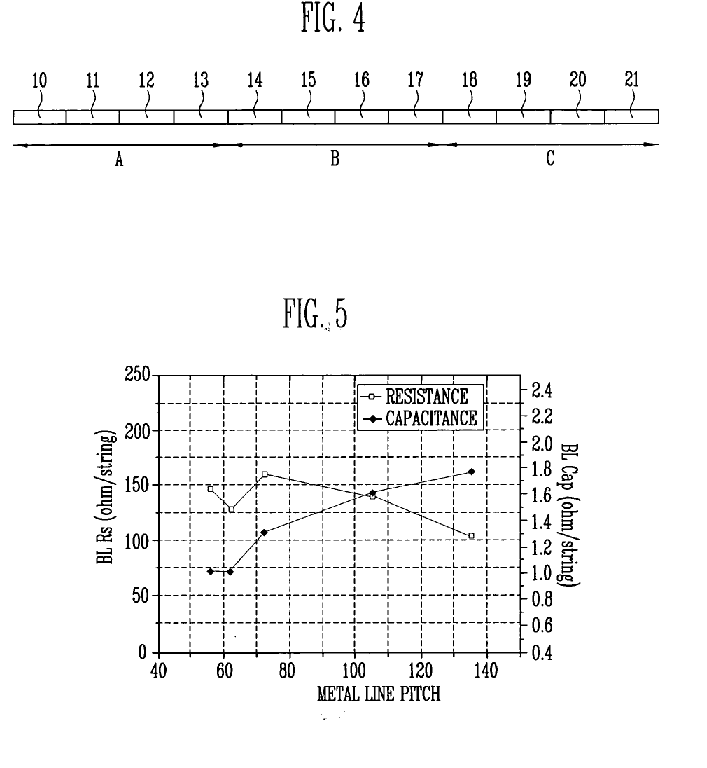

FIGS. 3A to 3E are cross-sectional views illustrating a method of forming a metal line of a semiconductor device according to an embodiment of the invention.

Referring to FIG. 3A, an interlayer insulating layer 102, a first insulating layer 104 and a glue layer 106 are sequentially formed over a semiconductor substrate 100 in which structures, such as a cell gate, source and drain select transistor gates, and a source and drain, are formed.

The first insulating layer 104 includes an oxide layer, and the glue layer 106 includes a lamination of a titanium (Ti) layer and a titanium nitride (TiN) layer. The glue layer 106 may be formed in-situ or ex-situ. The Ti layer of the glue layer 106 is preferably formed to a thickness of 10 Å to 200 Å, and the TiN layer of the glue layer 106 is preferably formed to a thickness of 50 Å to 200 Å. The glue layer 106 functions to prevent a lifting phenomenon between the first insulating layer 104 and tungsten in a subsequent tungsten formation process.

A mask pattern 108 is formed on the glue layer 106. The mask pattern 108 has a structure in which a silicon oxide nitride (SiON) layer, an amorphous carbon (a-Carbon) layer, a bottom anti-reflective coating (BARC) layer and a photoresist film are sequentially laminated. The glue layer 106 serves as an etch-stop layer when the mask pattern 108 is formed, and serves as a hard mask layer at the time of a subsequent trench etch process.

Referring to FIG. 3B, the glue layer 106 and the first insulating layer 104 are sequentially etched using the mask pattern 108 as a mask, forming trenches 110 (i.e., single damascene patterns). The mask pattern 108 is removed.

Referring to FIG. 3C, a second insulating layer is formed on the entire surface including the trench 110. The second insulating layer is perferably formed to a thickness of 10 Å to 200 Å using an oxide layer or a nitride layer.

A second insulating layer etch process is performed to form spacers 112 on the sides of the trenches 110. In the formation process of the spacers 112, top corners of the trench 110 are removed, thereby preventing over-hang at the inlet portions of the trenches 110 due to a tungsten formation process and a cleaning process (i.e., subsequent processes). The spacers 112 are formed on the sides of the trenches 110 in order to secure a space width between the trenches 110. In the case where the formation process of the spacers 112 is omitted, it is preferred that Radio Frequency (RF) etch cleaning be carried out in order to remove the top corners of the trenches 110 prior to a subsequent tungsten formation process.

The interiors of the trenches 110 are cleaned. The cleaning process preferably includes RF pre-cleaning or Reactive Ion (RI) pre-cleaning.

Referring to FIG. 3D, a metal layer 114 is formed on the entire surface so that the trenches 110 are gap-filled. The metal layer 114 is preferably formed in-situ using tungsten. At the time of the tungsten formation process, a nucleus is first generated and tungsten is formed using the nucleus as a seed. A method of generating the tungsten nucleus is preferably performed using an Atomic Layer Deposition (ALD) method, a Pulsed Nucleation Layer (PNL) method or a Low Rs W (LRW) method. The method of generating the tungsten nucleus using the LRW method is described in detail below.

A nucleus is preferably generated by sequentially spraying a first B₂H₆/WF₆ gas, a SiH₄/WF₆ gas, and a second B₂H₆/WF₆ gas over the semiconductor substrate. The first B₂H₆/WF₆ gas and the SiH₄/WF₆ gas are preferably sprayed in a temperature range of 250° C. to 400° C., and the second B₂H₆/WF₆ gas is preferably sprayed in a temperature range of 350° C. to 450° C. In this case, the process of spraying the first and second B₂H₆/WF₆ gases is performed once, whereas the process of spraying the SiH₄/WF₆ gas is performed once to five times in order to control a tungsten nucleus creation target. At the time of the second B₂H₆/WF₆ gas spray process, tungsten of an amorphous state or a tungsten nucleus of a β state is generated. If tungsten of the amorphous state or the tungsten nucleus of the β state is used as a seed, grain size can be increased when forming the tungsten layer.

After the tungsten nucleus is generated, a tungsten layer is formed preferably using a H₂ gas. The tungsten layer is preferably formed in a temperature range of 350° C. to 450° C.

Referring to FIG. 3E, a polishing process is performed until a top surface of the first insulating layer 104 is exposed, thus forming metal lines 116. At the time of the polishing process, the glue layer 106 is also removed.

As described above, the barrier metal layer is not formed within the trenches 110, but tungsten is gap-filled in the trenches. Thus, the volume of tungsten can be maximized, and the resistance of the metal line can be reduced. Furthermore, when the tungsten nucleus is generated within the trenches 110, the tungsten nucleus is not generated on the TiN layer (i.e., the barrier metal layer), but the tungsten nucleus is generated on the first insulating layer 104. Accordingly, there are advantages in that the grain size of tungsten can be increased and the resistivity can be reduced.

Furthermore, the glue layer 106 is formed only on the etched first insulating layer 104. Therefore, a phenomenon in which the glue layer 106 lifts between the first insulating layer 104 and tungsten at the time of the tungsten formation process can be prevented. The tungsten nucleus is preferably generated within the trenches 110 using the B₂H₆/WF₆ gas and the SiH₄/WF₆ gas. Accordingly, adhesive force between the first insulating layer 104 and tungsten within the trenches 110 can be enhanced at the time of the tungsten formation process, and the resistivity can be improved.

FIG. 4 is a view illustrating a Low Rs W (LRW) method according to the invention.

Referring to FIG. 4, the LRW method illustratively includes performing the processes of (10) supplying a B₂H₆ source gas, thus chemically adsorbing a source of one layer on the surface of a wafer, (11) purging physically adsorbed excessive sources by flowing a purge gas, (12) supplying a WF₆ reaction gas to the source of one layer so that a desired tungsten nucleus is formed through a chemical reaction of the source of one layer and the reaction gas, and (13) purging excessive reaction gases by flowing a purge gas. The process is referred to as a “first cycle A.” The first cycle A is performed only once.

After the first cycle A is performed, the LRW method illustratively includes performing the processes of (14) supplying a SiH₄ source gas in order to chemically absorb the source of one layer on the surface of the wafer, (15) purging physically adsorbed excessive sources by flowing a purge gas, (16) supplying the WF₆ reaction gas to the source of one layer in order to obtain a desired tungsten nucleus through a chemical reaction of the source of one layer and the reaction gas, and (17) purging excessive reaction gases by flowing a purge gas. The process is referred to a “second cycle B.” The second cycle B is performed once to five times in order to control the tungsten nucleus creation target.

After the second cycle B is performed, the LRW method illustratively includes performing the processes of (18) supplying the B₂H₆ source gas in order to chemically absorbing the source of one layer on the surface of the wafer, (19) purging physically adsorbed excessive sources by flowing a purge gas, (20) supplying the WF₆ reaction gas to the source of one layer in order to obtain a desired tungsten nucleus through a chemical reaction of the source of one layer and the reaction gas, and (21) purging excessive reaction gases by flowing a purge gas. The process is referred to as a “third cycle C.” The third cycle C is performed once.

FIG. 5 is a graph showing resistance values and capacitance values when the invention is applied.

From FIG. 5, it can be seen that as the pitch of a metal line decreases, that is, devices shrinks to 60 nm or less, resistance values and capacitance value are decreased or kept to a constant value.

As described above in detail, the invention has the following advantages.

First, the barrier metal layer is not formed within the trenches, but tungsten is gap-filled within the trenches. Accordingly, the volume of tungsten can be maximized, and the resistance of a metal line can be reduced.

Second, when generating a tungsten nucleus within the trenches, a tungsten nucleus is not generated on the TiN layer (i.e., the barrier metal layer), but is generated on the first insulating layer. Accordingly, there are advantages in that the grain size of tungsten can be increased, and the resistivity can be decreased.

Third, the glue layer is formed only on the etched first insulating layer. Accordingly, a phenomenon in which the glue layer lifts the first insulating layer and tungsten at the time of the tungsten formation process can be prevented.

Fourth, the tungsten nucleus is generated within the trenches using the B₂H₆/WF₆ gas and the SiH₄/WF₆ gas. Thus, adhesive force between the first insulating layer and tungsten within the trenches can be increased at the time of the tungsten formation process, and the resistivity can be improved.

Fifth, tungsten (i.e., a metal line material) can be used even in devices of 60 nm, 50 nm, or 45 nm in size without an adverse effect on electrical characteristics.

Sixth, the metal line that is improved as described above is formed using tungsten, thereby saving costs.

While the invention has been described with reference to particular illustrative embodiments, it is not to be restricted by the embodiments but only by the appended claims, as those skilled in the art can change or modify the embodiments without departing from the scope and spirit of the invention.

What is claimed is:

1. A method of forming a metal line of a semiconductor device, comprising the steps of:
forming an insulating layer and a glue layer on a semiconductor substrate;
removing a portion of the glue layer and the insulating layer to form trenches;
forming a metal layer over the semiconductor substrate including the trenches and the glue layer; and
performing a polishing process until the insulating layer is exposed, thus forming a metal line.

2. The method of claim 1, wherein the glue layer includes a lamination of titanium (Ti) and a titanium nitride (TiN) layer.

3. The method of claim 1, comprising forming the glue layer in-situ or ex-situ.

4. The method of claim 2, comprising forming titanium (Ti) of the glue layer to a thickness of 10 Å to 200 Å, and forming the TIN layer of the glue layer to a thickness of 50 Å to 200 Å.

5. The method of claim 1, further comprising the steps of:
before the trenches are gap-filled, forming spacers on sidewalls of the trenches; and
cleaning the interiors of the trenches.

6. The method of claim 5, wherein the step of forming the spacers comprises the steps of:
forming an insulating layer over the semiconductor substrate including the trenches; and
performing an etch process to form the spacers on the sidewalls of the trenches.

7. The method of claim 6, comprising forming the insulating layer to a thickness of 10 Å to 200 Å using an oxide layer or a nitride layer.

8. The method of claim 5, comprising, when forming the spacers, removing top corners of the trenches.

9. The method of claim 5, comprising cleaning the interiors of the trenches using Radio Frequency (RF) pre-cleaning or Reactive Ion (RI) pre-cleaning.

10. The method of claim 5, wherein in the case where the spacers are not formed, performing the cleaning process to remove top corners of the trenches.

11. The method of claim 1, comprising forming the metal layer in-situ using tungsten.

12. The method of claim 11, comprising, at the time of the tungsten formation process, forming a nucleus, and forming tungsten using the nucleus as a seed.

13. The method of claim 12, comprising forming the tungsten nucleus using an Atomic Layer Deposition (ALD) method, a Pulsed Nucleation Layer (PNL) method, or a Low Rs W (LRW) method.

14. The method of claim 13, comprising generating the tungsten nucleus using an LRW method including the steps of generating the nucleus by sequentially spraying a first B₂H₆/WF₆ gas, a SiH₄/WF₆ gas, and a second B₂H₆/WF₆ gas.

15. The method of claim 14, comprising spraying the first B₂H₆/WF₆ gas and the SiH₄/WF₆ gas in a temperature range of 250° C. to 400° C., and spraying the second B₂H₆/WF₆ gas in a temperature range of 350° C. to 450° C.

16. The method of claim 14, comprising performing the process of spraying the first and second B₂H₆/WF₆ gas once, and performing the process of spraying the SiH₄/WF₆ gas once to five times.

17. The method of claim 14, comprising generating tungsten of an amorphous state or a tungsten nucleus of a β-state in the process of spraying the second B₂H₆/WF₆ gas.

18. The method of claim 12, wherein after forming the nucleus, forming tungsten using H₂ gas in a temperature range of 350° C. to 450° C.
